(19) United States
(12) Patent Application Publication
(10) Pub. No.: US 2004/0222842 A1
(43) Pub. Date: Nov. 11, 2004

(54) Systems and methods for generating a reference voltage

(76) Inventor: Ronnie Edward Owens, Fort Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/862,552

(22) Filed: Jun. 7, 2004

Related U.S. Application Data
(63) Continuation-in-part of application No. 10/292,971, filed on Nov. 13, 2002.

(51) Int. Cl. H03M 1/00

(52) U.S. Cl. 327/541

(57) ABSTRACT

Systems and methods for generating a voltage reference are provided. One embodiment, among others, provides a reference-voltage generating circuit that incorporates a biasing diode together with a first field effect transistor (FET) connected in series with the biasing diode. A first reference-voltage is generated at a connection point between the biasing diode and the first FET, the first FET being selectively biased to produce a source-drain current that is substantially the same as a current passing through the biasing diode. The current passing through the biasing diode configures the biasing diode to operate as a linear resistor having a voltage drop that varies at a desired rate when the diode is subjected to a change in temperature.

### CROSS-REFERENCE TO RELATED APPLICATION

This application is a continuation-in-part of and claims priority to copending U.S. utility application entitled, “Systems and methods for altering timing edges of an input signal,” having Ser. No. 10/292,971 and filed on Nov. 13, 2002, which is entirely incorporated herein by reference.

### FIELD OF THE INVENTION

The present invention generally relates to voltage references. More particularly, the present invention relates to systems and methods for generating a reference voltage.

### DESCRIPTION OF THE RELATED ART

A reference voltage generating circuit (RVGC) is typically designed to generate a stable reference voltage that does not vary significantly when certain parameters associated with the RVGC, undergo undesirable variations. A first example of such a parameter, is the power supply that is connected to the RVGC. When the power supply voltage fluctuates, the generated reference voltage also has a tendency to fluctuate. This tendency to fluctuate is countered in the RVGC by compensating circuitry that operates to constrain the generated reference voltage to a stable, desired value. A second example of a parameter that may undergo variations, relates to operating temperature. Here, a temperature change may result in current flows and voltage drops in the RVGC having a tendency to change. Again, this tendency to change is countered by suitable circuitry so as to produce a stable reference voltage output.

Obviously, the quality of the generated reference voltage is dependent upon the quality of the RVGC, which in turn is dependent upon various trade-offs related to, for example, circuitry cost, performance requirements, and quality of circuit design. To illustrate a trade-off related to performance requirements, in a first situation wherein the RVGC is located inside an air-conditioned building, the influence of temperature may be deemed less important than the influence of power supply variations. Consequently, the RVGC may be designed primarily to compensate for power supply variations, with temperature compensation features added in a secondary fashion. In a second situation, the RVGC may be located in an outside location subjected to extreme temperature variations but operating from a battery where expectedly, the power supply variations are deemed less critical. In this second instance, the RVGC may be designed primarily to counter the effects of temperature.

Certain RVGC configurations permit an operator to perform manual adjustments to counter the effects of one or more operating parameters upon the generated reference voltage. Unfortunately, in adjusting to counter variations caused by a first operating parameter—for example, voltage, the operator may be unable to effectively compensate for variations in a second operating parameter—for example, temperature. To further illustrate this point, attention is drawn to U.S. Pat. No. 5,233,637 “System for generating an analog regulating voltage” by Koerner et. al. Koerner discloses in part, “an adjustable control for a user is provided to, for example, compensate for process variation.” (Col. 2, lines 12-14). In this case, the adjustment does not permit compensating for temperature variations as well as power supply variations independent of one another.

Attention is now drawn to prior art FIG. 1 to further illustrate this aspect. RVGC 100 comprises a digital-to-analog (DAC) circuit 105 coupled to a constant current source 125. The reference voltage that is generated is available on output line 120. DAC 105 includes a digital-to-analog decoder which is provided with a digital word that is converted to a corresponding analog voltage applied to a transistor array, of which two transistors 110 and 115 are shown in FIG. 1. The digital word is selected to set the amplitude of the current flowing through the constant current source 125 to a desired value. Any variation in the generated constant current, and consequently in the generated reference voltage on line 120, can be compensated by appropriately changing the value of the digital word. Therefore, a change in the constant current due to a change in the power supply can be compensated by changing the digital word. Unfortunately, this process of providing a new digital word, may prove unsuitable to simultaneously compensate for a change in the constant current wherein the change in current has been caused by a change in operating temperature. Consequently, it can be appreciated that such a circuit can compensate for a variation in a first parameter but may not be effective in compensating for variation in a second parameter simultaneously.

Based on the foregoing, it should be understood that there is a need for improved systems and methods that address these and other perceived shortcomings of the prior art.

### SUMMARY OF THE INVENTION

One embodiment, among others, provides a reference-voltage generating circuit that incorporates a biasing diode together with a first field effect transistor (FET) that is connected in series with the biasing diode. A first reference-voltage is generated at a connection point between the biasing diode and the first FET, the first FET being selectively biased to produce a source-drain current that is substantially the same as a current passing through the biasing diode. The current passing through the biasing diode configures the biasing diode to operate as a linear resistor having a voltage drop that varies at a desired rate when the diode is subjected to a change in temperature.

In a second embodiment, a method for generating a reference voltage having a desired temperature coefficient, is provided. The method comprises the steps of providing a diode having a first temperature coefficient; connecting the diode to a first FET such that a forward current passing through the diode is substantially the same as a source-drain current passing through the first FET. The method further comprises providing to the first FET, a first control voltage that is selected to obtain a first desired forward current through the diode; and generating from the first desired forward current, a first reference voltage having the desired temperature coefficient.

Other systems and methods, features, and advantages of the present invention will be or become apparent to one with skill in the art upon examination of the following drawings and detailed description. It is intended that all such additional systems, methods, features, and advantages included within this description and be within the scope of the present invention.

### BRIEF DESCRIPTION OF THE DRAWINGS

The invention can be better understood with reference to the following drawings. The components in the drawings are not necessarily drawn to scale, emphasis instead being placed upon clearly illustrating the principles of the present invention. Moreover, in the drawings, like reference numerals designate corresponding parts throughout the several views.

FIG. 1 is a circuit schematic of a prior art reference voltage generating circuit.

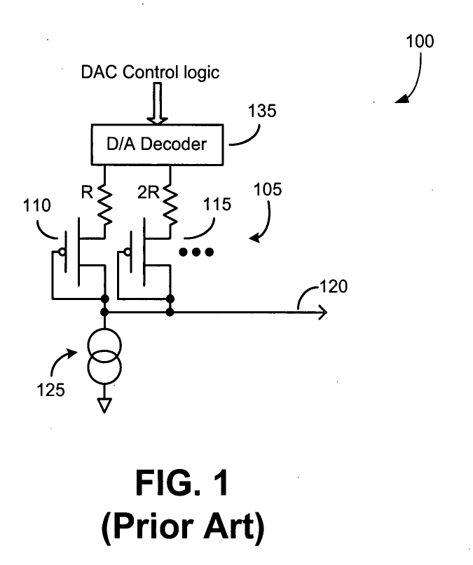

FIG. 2 depicts a block diagram of a reference voltage generating circuit providing two reference voltages to a load circuit.

FIG. 3 illustrates one exemplary embodiment of the reference voltage generating circuit of FIG. 2.

FIG. 4 shows a voltage vs. current graph of a biasing diode that is used in the reference voltage generating circuit of FIG. 3.

FIG. 5 shows a second exemplary embodiment of the reference voltage generating circuit of FIG. 2.

FIG. 6 illustrates one exemplary embodiment of the load circuit of FIG. 2.

FIG. 7 is a flowchart to show the steps involved in configuring the exemplary embodiment of FIG. 5.

### DETAILED DESCRIPTION

Having summarized various aspects of the present invention, reference will now be made in detail to the description of the invention as illustrated in the drawings. While the invention will be described in connection with these drawings, there is no intent to limit it to the embodiment or embodiments disclosed therein. On the contrary, the intent is to cover all alternatives, modifications and equivalents included within the spirit and scope of the invention as defined by the appended claims.

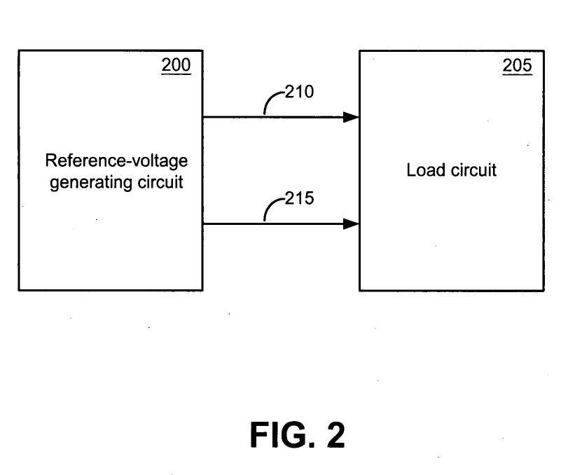

Attention is drawn to FIG. 2, which depicts a block diagram of a reference voltage circuit (RVGC) 200 that provides two reference voltages through lines 210 and 215, to a load circuit 205. It will be understood that the two reference voltages may be identical in a first embodiment, while in a second embodiment the two voltages may differ from one another in one or more parameters such as amplitude, polarity, and temperature coefficient. RVGC 200 and load circuit 205 will be explained in further detail below.

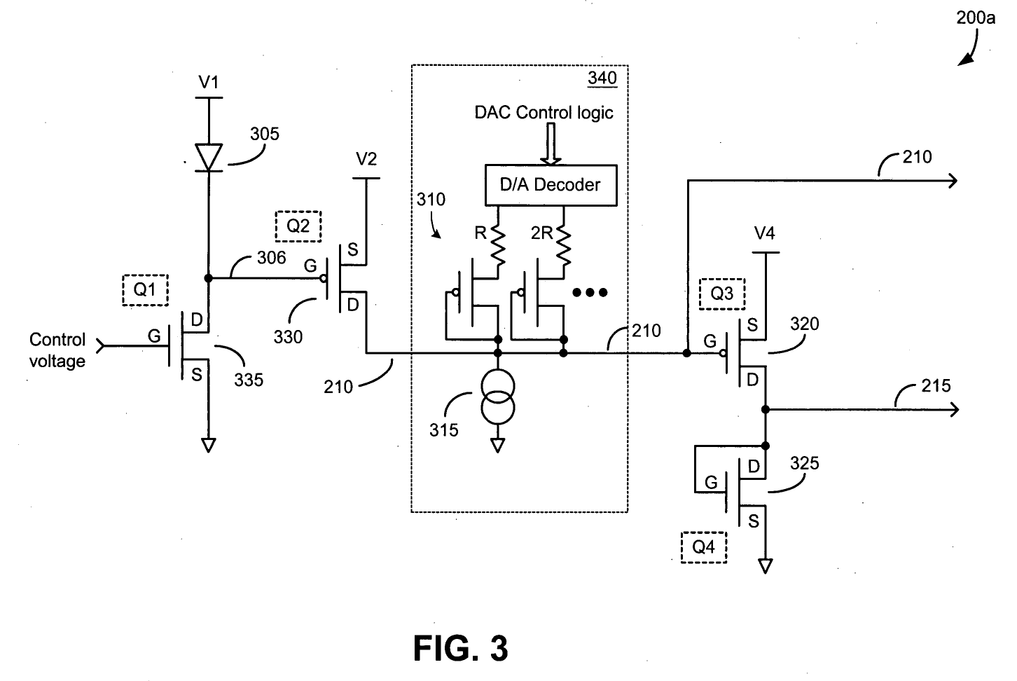

FIG. 3 illustrates a RVGC 200a, which is a first exemplary embodiment of the RVGC 200 of FIG. 2. Attention is drawn to block 340, which illustrates a voltage generating circuit (VGC) comprising a constant-current source 315 and a digital-to-analog converter (DAC) 310 that is programmed, typically using a digital word, to set a desired current flow through the constant-current source 315. The generated voltage appears at the junction of DAC 310 and constant-current source 315, on line 210. The circuitry of block 340 may be located entirely within one integrated circuit (IC), or alternatively, DAC 310 may be located inside a first IC while constant-current source 315 may be located outside the first IC.

The DAC 310 can be dynamically programmed so as to provide the appropriate current through the constant-current source 315 whenever there is, for example, an undesirable fluctuation in the power supply voltage V3. Alternatively, DAC 310 can be programmed to compensate for a variation in operating temperature. Unfortunately, an optimal compensation cannot be carried out for both these changes—voltage and temperature, in a single, simultaneous adjustment.

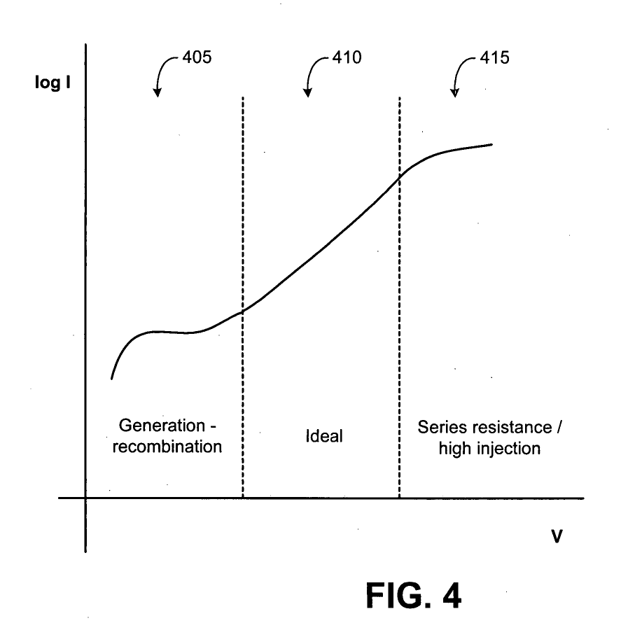

Attention is now drawn to the biasing diode 305. A forward-bias current flowing through diode 305 is selected such that diode 305 operates as a linear resistor having a voltage drop that varies at a desired rate when the diode is subjected to a change in temperature. The voltage-vs.-current characteristic for setting the diode operation will be explained using FIG. 4 in more detail below.

The forward-bias current flowing through diode 305 is controlled by one or more elements that are connected to it. The first element comprises transistor 335, which is labeled Q1 in FIG. 3. Transistor 335 is shown in this example as an NMOS FET, with a drain terminal connected to the cathode of biasing diode 305 and a source terminal connected to ground. A control voltage is provided to a gate terminal of transistor 335. The connection between transistor 335 and diode 305 may be considered a series-connection because the source-drain current of the transistor 335 is the same as the forward current flowing through the diode 305.

While transistor 335 is shown as an NMOS FET in FIG. 3, it will be understood that in an alternative embodiment, a PMOS FET or another type of transistor may be used instead. Understandably, when a PMOS FET is used, the terminals of the PMOS FET will be provided with power supply connection(s) of appropriate polarity and amplitude. Furthermore, persons of ordinary skill in the art will recognize that several other alternative connections, including certain parallel connections, can be implemented between diode 305, transistor 335, and other elements that are not shown.

The control voltage provided at the gate terminal of transistor 335 is selected to bias the transistor 335 into a conduction region wherein the source-drain current, and consequently the forward current of the diode 305, places the diode in operation as a linear resistor. As one example, the biasing can be selected so as to place transistor 335 in a saturated region of operation.

In the embodiment shown in FIG. 3, the voltage drop across the source-drain terminals of transistor 335 is the same as the generated reference voltage. this generated reference voltage is available on line 306, which is at the junction of the drain terminal of transistor 335 and the cathode of diode 305. It will be understood that in other embodiments, the reference voltage may be derived at other locations.

The generated reference voltage on line 306 is provided to a gate terminal of a second transistor 330 (labeled Q2 in FIG. 3). In this embodiment, the drain terminal of transistor 330 is connected via line 210 to the circuitry of block 340. Transistor 330 can be used for several purposes, such as, but not limited to, providing gain to the reference voltage of line 306, adjusting the current through diode 305, providing a temperature coefficient of an opposite polarity, and acting as a buffer to the reference voltage of line 306. The reference-voltage available on line 210 is the first generated reference voltage from RVGC 200a.

It can be observed from FIG. 3, that at least three elements can be operated to influence the characteristic of the first generated reference voltage from RVGC 200a. These three elements are: transistor 335, transistor 330, and DAC 310. The method of carrying out this procedure will be explained below using additional figures.

The second generated reference voltage from RVGC 200a appears on line 215. In this embodiment, the second voltage is generated from the first reference voltage by utilizing a circuit comprising transistors 320 and 325. The biasing, as well as operating characteristics of transistors 320 and 325, influence the characteristics such as, for example, amplitude, polarity, and temperature coefficient, of the second generated reference voltage.

Attention is now drawn to FIG. 4, which shows a voltage vs. current graph of a biasing diode, for example the biasing diode 305 of FIG. 3. In region 405, the forward-biased diode current flow (log I) causes the diode to operate in a mode wherein the electron-holes of the semiconductor device of the diode are in a state of generation-recombination. It can be observed that in this operating mode, the current-voltage response is non-linear in nature. In region 415, the forward-biased diode current flow (log I) causes the diode to operate in a mode wherein the series resistance of the diode becomes very low, consequently leading to high carrier injection. Here again, as in region 405, the current-voltage response is non-linear in nature.

In region 410, the forward-bias current is such that the voltage-current response is linear in nature, and this is the region of operation desired for use in the circuit embodiment of FIG. 3 and other embodiments.

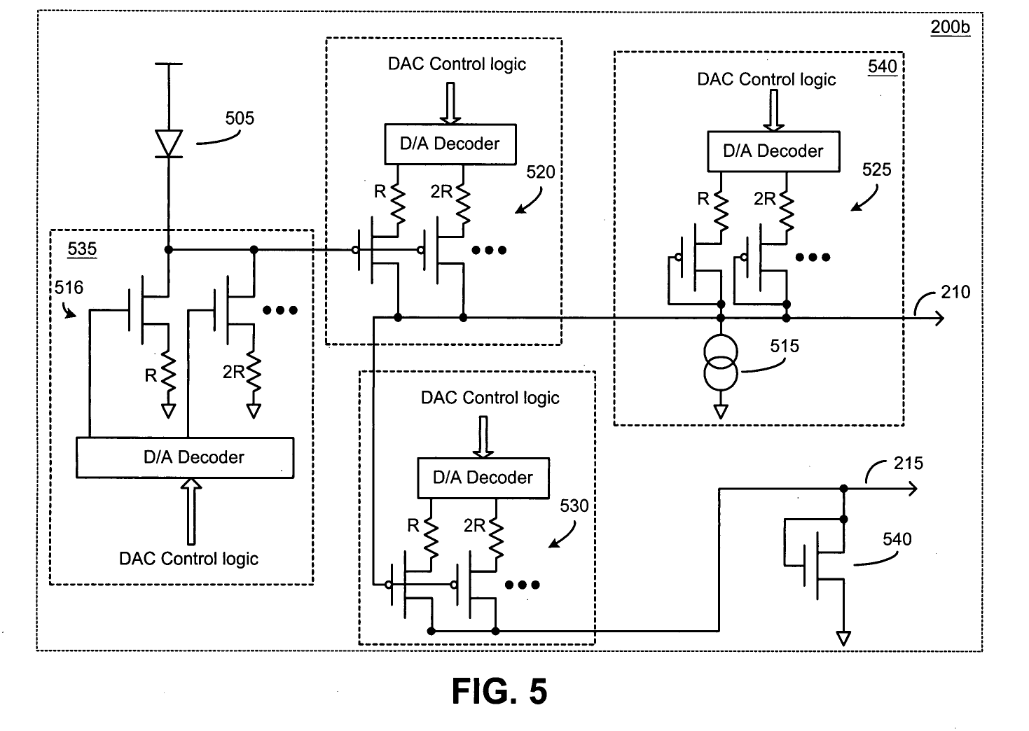

FIG. 5 illustrates an RVGC 200b, which is a second exemplary embodiment of the RVGC 200 of FIG. 2. The current flowing through biasing diode 505 is influenced in part, by DAC 516. The DAC control logic of DAC 516 comprises a digital word that determines the biasing of the DAC transistors, and consequently the drain-source currents of the parallel transistors that cumulatively influence the forward current of diode 505. While DAC 516 is shown using a resistive ladder network, persons of ordinary skill in the art will recognize that this has been done merely for illustration purposes. Alternative DAC configurations can be used to set the forward bias current flowing through diode 505. Such DAC configurations include those that use appropriately-scaled width/length (W/L) ratio of transistor fabrications inside integrated circuits.

The current through diode 505 is further influenced in part, by DAC 520. Here again, the transistors that constitute DAC 520 may be set to conduct in a specified manner by setting an appropriate digital word through the DAC control logic input of DAC 520.

DAC 525 provides further control for setting the current through constant current source 515, which in turn influences the forward current flowing through diode 505. The characteristics of the various DACs (e.g. power supply amplitude, conduction characteristics/biasing of the transistors, thermal characteristics of the transistors etc.) can be selected to provide appropriate characteristics, such as amplitude, polarity, and temperature coefficient, for the reference voltage that is output on line 210. In one example, such a selection may include using a positive temperature transistor in conjunction with a negative temperature transistor.

DAC 530 and transistor 540 constitute a current-mirror circuit to generate the second reference voltage output on line 215.

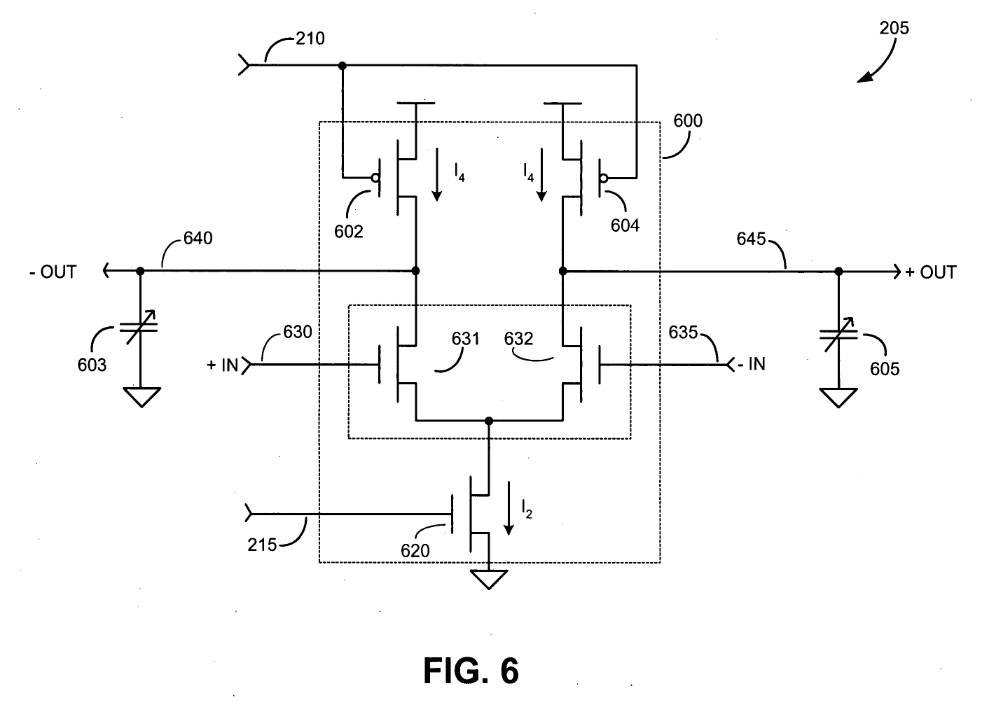

FIG. 6 illustrates one exemplary embodiment of the load circuit 205 of FIG. 2. The invention relating to this figure has been disclosed in the copending U.S. utility application entitled “Systems and methods for altering timing edges of an input signal,” having Ser. No. 10/292,971, filed on Nov. 13, 2002. Briefly described, FIG. 6 illustrates a system for altering the timing edges of a differential input signal provided via input lines 630 and 635. Load circuit 205 comprises a differential amplifier having two transistors 631 and 632 whose drain terminals are connected to a pair of load transistors 602 and 604. The load transistors 602 and 604 are biased to operate as a pair of controllable resistances. The biasing is achieved through the first reference voltage, provided via line 210, to the commonly-connected gate terminals of load transistors 602 and 604. These load resistances operate in conjunction with respective variable capacitances 503 and 505, so as to provide a controllable differential delay to the differential input signal.

Transistor 620 operates as a current source to the differential transistor pair 631 and 632. The current through transistor 620 is controlled by the second reference voltage that is provided through line 215, to a gate terminal of transistor 620. It will be observed that the reference voltages on lines 210 and 215 are provided to the load circuit 205, by the RVGC 200 of FIG. 2.

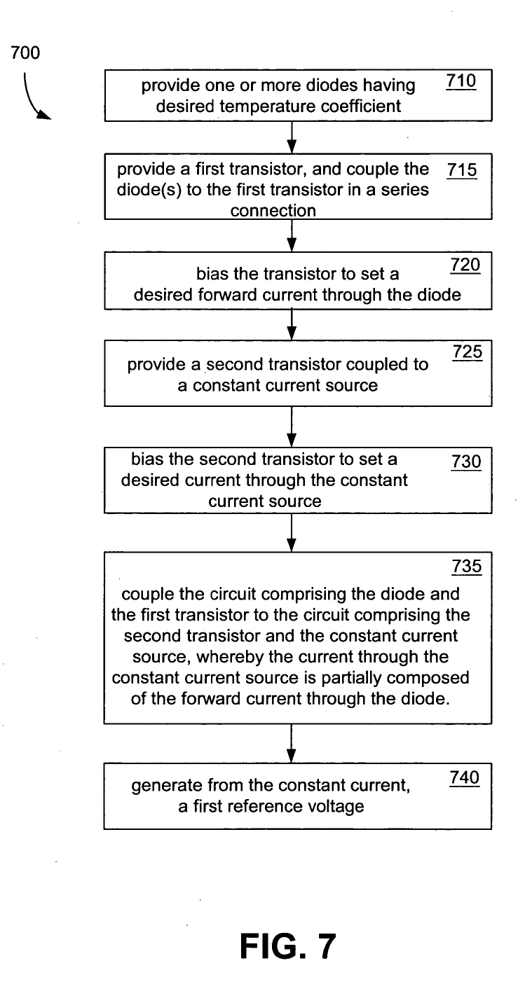

FIG. 7 is a flowchart to show the steps involved in configuring the exemplary embodiment of FIG. 5. In this regard, each block of the flowchart represents a module segment or portion of code which comprises one or more executable instructions for implementing the specified logical function(s). It should also be noted that in some alternative implementations the functions noted in various blocks of FIG. 7 may occur out of the order in which they are depicted. For example, two blocks shown in succession in FIG. 7 may, in fact, be executed substantially concurrently. In other embodiments, the blocks may sometimes be executed in the reverse order depending upon the functionality involved. In certain other embodiments, only a few of the blocks may be executed.

In block 710, one or more diodes are selected based on a desired temperature coefficient. In FIG. 5, only one such diode, diode 505, is shown, whereas in other embodiments, multiple diodes can be cascaded if desired. As one example of the diode selection process, a (p+/n-well) diode having a temperature coefficient of +2 mV/° C. is selected based on the polarity and amplitude of its temperature coefficient. Then, if a +6 mV/° C. temperature coefficient characteristic is desired of the generated reference voltage, three such diodes will be serially cascaded in place of the single diode 505 that is shown in FIG. 5. It will be understood that other temperature-related characteristics, including negative a temperature coefficient, may be optionally obtained by appropriate selection of other types and numbers of diodes.

In block 715, a first transistor is coupled to the diode(s) in a series connection. In FIG. 5, this first transistor is part of DAC 516, which is serially connected to diode 505 as shown. In block 720, the first transistor is biased to set a desired forward current through the diode 505. In the case of FIG. 5, this step comprises providing DAC 516 with a digital word (DAC control logic), that causes one or more transistors of the DAC to conduct and generate a current flowing through diode 505. The amplitude of the current is selected so as to place diode 505 in the operating region 410 (ideal region) as described in FIG. 4. In this region diode 505 operates as a linear resistor having a temperature characteristic of, for example, +2 mV/° C.

In block 725, a second transistor is provided, the second transistor being coupled to a constant current source. This second transistor is a part of DAC 525, while the constant current source comprises source 515. DAC 525 is then provided with a digital word that sets the current through the second transistor, and other transistors of DAC 525, and consequently determines the current through the constant current source 515.

The circuit comprising the first transistor (DAC 516) and diode 505, is then coupled to the circuit comprising the second transistor (DAC 525) and the constant current source 515. This coupling is carried out in FIG. 5, via DAC 520. It will be understood that DAC 520 may also be provided with an appropriate digital control word so as to suitably configure the operating characteristics of DAC 520. Such characteristics, as mentioned above, include gain, temperature coefficient, and polarity, for example.

Once DACs 516, 525, and 520 have been suitably configured, it can be observed from FIG. 5, that the current through the constant current source 515 incorporates a part of the forward current flowing through diode 505, thereby incorporating in part, the temperature coefficient behavior of diode 505. Additionally, the current through the constant current source 515 also incorporates the currents and temperature coefficient behavior of DACs 520 and 525. Such behaviors can be selected to cancel each other out, or to be additive in their influence upon the generated reference voltage. Consequently, the combination of these currents can be programmed to provide a desired temperature coefficient behavior as well as a desired stability with reference to power supply fluctuations.

In block 740, a first reference voltage is generated from the constant current flowing through the constant current source 515. In the exemplary embodiment of FIG. 5, this reference voltage is generated with reference to ground, across the constant current source 515, but it will be understood that in other embodiments a voltage drop can be generated across other elements through one or more current flows.

The first reference voltage is generated on line 210 of FIG. 5. This first generated voltage is further provided to DAC 530, which is serially connected to transistor 540. The circuit comprising DAC 530 and transistor 540 constitute a current-mirror circuit that generates a second reference voltage on line 215. By appropriate selection of the type of transistors inside DAC 530 and by configuring the current flow through these transistors, the second reference voltage can be set to have a desired characteristic—for example, polarity, amplitude, and temperature coefficient, that can be different from that of the first reference voltage.

It should be emphasized that the above-described embodiments of the present invention, particularly, any embodiments, are merely possible examples of implementations, merely set forth for a clear understanding of the principles of the invention. Many variations and modifications may be made to the above-described embodiment(s) of the invention without departing substantially from the spirit and principles of the invention. For example, it will be relevant to point out that the transistors shown in the various figures are FETs that are used merely for purposes of explanation. Other transistors, such as NPN and PNP silicon transistors may be used in alternative embodiments. Also, the series connections referred to above, may be replaced by parallel connections. All such modifications and variations are intended to be included herein within the scope of this disclosure and the present invention and protected by the following claims.

I claim:

1. A reference-voltage generating circuit, the circuit comprising:
a biasing diode; and
a first field effect transistor (FET) connected in series with the biasing diode, a first reference-voltage being generated at a connection point between the biasing diode and the first FET, the first FET being selectively biased to produce a source-drain current that is substantially the same as a current passing through the biasing diode, and wherein the current passing through the biasing diode configures the biasing diode to operate as a linear resistor having a voltage drop that varies at a desired rate when the diode is subjected to a change in temperature.

2. The circuit of claim 1 wherein the first FET is a PMOS FET and the first reference-voltage is generated at a drain terminal of the PMOS FET.

3. The circuit of claim 1 wherein the first FET is a NMOS FET and the first reference-voltage is generated at a source terminal of the PMOS FET.

4. The circuit of claim 1, wherein a change in amplitude of the first reference-voltage is linearly related to a change in amplitude of the forward current passing through the biasing diode.

5. The circuit of claim 1, further comprising:
a constant current source; and
a second FET connected to the constant current source, wherein the combination of the second FET and the constant current source is operative, together with the first FET, to set the current passing through the diode.

6. The circuit of claim 5, further comprising:
a third FET; and
a fourth FET, wherein the third and fourth FETs are connected together in a circuit to receive the first reference-voltage and generate a second reference-voltage.

7. The circuit of claim 6, wherein at least one of an amplitude and a polarity of the second reference-voltage is different than at least one of an amplitude and a polarity of the first reference-voltage

8. The circuit of claim 5, wherein the constant current source is located inside an integrated circuit, and the biasing diode and the first FET are located outside the integrated circuit.

9. The circuit of claim 8, wherein a current through the constant current source is preset to a predetermined amplitude.

10. The circuit of claim 1, wherein the first FET is part of an digital-to-analog converter.

11. The circuit of claim 10, wherein selective biasing of the first FET comprises providing a digital word to the digital-to-analog converter.

12. A method for generating a reference voltage having a desired temperature coefficient, the method comprising:
providing a diode having a first desired temperature coefficient;
providing a first field effect transistor (FET);
connecting the diode and the first FET such that a forward current passing through the diode is substantially the same as a source-drain current passing through the first FET;
providing to the first FET, a first control voltage selected to obtain a first desired forward current through the diode; and
generating from the first desired forward current, a first reference voltage having the desired temperature coefficient.

13. The method of claim 12, wherein the desired temperature coefficient is a non-zero temperature coefficient.

14. The method of claim 13, wherein the first desired forward current is selected to
configure the diode to operate in a linear operating region.

15. The method of claim 14, wherein the first control voltage is selected to configure the first FET to operate in a saturated operating region of the source-drain current.

16. The method of claim 14, further comprising:
providing a second FET;
providing to a gate terminal voltage of the second FET, the first reference voltage having the desired temperature coefficient; and
connecting one of a drain and a source terminal of the second FET to a constant current source, the combination of the second FET and the constant current source operating together with the first FET, to selectively set the first desired forward current through the diode.

17. The method of claim 16, further comprising:
providing a third FET and a fourth FET;
connecting the third and fourth FETs in series;
providing to a gate terminal voltage of the third FET, the first reference voltage having the desired temperature coefficient; and
generating a second reference-voltage at a connection point between the third and fourth FETs.

18. The method of claim 17, wherein at least one of an amplitude, a polarity, and a temperature coefficient of the second reference-voltage is different than at least one of an amplitude, a polarity, and a temperature coefficient of the first reference-voltage.

19. The method of claim 12, wherein the first FET is part of a digital-to-analog converter circuit.

20. The method of claim 19, wherein the first control voltage is selected by using a digital word provided to the digital-to-analog converter circuit.

21. A method for generating a reference voltage having a desired temperature coefficient, the method comprising:
setting a forward current through a diode, wherein the diode is selected to have a first temperature coefficient;
setting an amplitude of a current through a constant-current source, wherein the current includes at least a portion of the forward current; and
generating from the current through the constant-current source, the reference voltage having the desired temperature coefficient.

22. The method of claim 21, wherein the constant-current source has a second temperature coefficient that is different than the first temperature coefficient.
